(19) United States
(12) Patent Application Publication
(10) Pub. No.: US 2009/0308904 A1
(43) Pub. Date: Dec. 17, 2009

(54) WIRE FEED SYSTEM AND METHOD OF OPERATING THE SAME

(75) Inventors: Wei Qin, Lansdale, PA (US); Edward T. Laurent, Maple Glen, PA (US)

Correspondence Address: KULICKE AND SOFFA INDUSTRIES, INC., 1005 VIRGINIA DRIVE, FORT WASHINGTON, PA, 19034, US

(73) Assignee: KULICKE AND SOFFA INDUSTRIES, INC., Fort Washington, PA (US)

(21) Appl. No.: 11/917,181

(22) PCT Filed: Nov. 9, 2006
(86) PCT No.: PCT/US06/43760

§ 371 Date: Dec. 11, 2007

(51) Int. Cl. B65H 59/10; B65H 51/00; B65H 51/20; B23K 20/00; H01L 21/60

(52) U.S. Cl. 226/1; 226/195; 242/418

(57) ABSTRACT

A wire feed system for a wire bonding machine is provided. The wire feed system includes (1) a wire supply, and (2) an air guide for receiving a length of wire from the wire supply. The air guide has an air inlet for receiving a pressurized fluid. The wire feed system is configured to apply a variable tension to the length of wire received by the air guide.

### FIELD OF THE INVENTION

The present invention relates to wire feed systems, and more particularly, to improved wire feed systems for wire bonding machines.

### BACKGROUND OF THE INVENTION

In the manufacturer and processing of various semiconductor devices, wire bonding machines are often used to connect components in the devices. Such wire bonding machines typically include a wire feed system for feeding a wire on a wire spool to a bond head of the wire bonding machine. The bond head of the wire bonding machine typically carries a transducer (e.g., an ultrasonic transducer) and a bonding tool (e.g., a capillary tool, a wedge tool, etc.).

One function of the wire feed system of a wire bonding machine is to apply air pressure (or the like) to the wire for controlling the wire, for example, (1) to prevent wire damage during high speed motions, (2) for seating a ball of the wire in a capillary tool, etc. The wire extends from the wire feed system to a wire tensioning device adjacent the bond head.

U.S. Pat. No. 5,402,927 (“Adjustable Wire Tensioning Apparatus”) to Frasch discloses wire feed system 10 including: wire spool 11, stream of air 14, and limit stops 15, 16, amongst other parts. Stream of air 14 urges wire 12 to form a loose loop that is limited by limit stops 15 and 16. Wire 12 extends from wire feed system 10 to tensioning device 19, where tensioning device 19 applies a much greater force to the wire than the force applied by wire feed system 10. Tensioning device 19 works in conjunction with different air pressure sources such that the force applied via tensioning device 19 may be varied during the wire bonding cycle.

Thus, the '927 patent discloses an adjustable wire tensioning device. Unfortunately, the system disclosed in the '927 patent is deficient in providing an efficient variable tension to the wire in certain applications. For example, because the tensioning device is supported at the bond head, the systems used to provide adjustable tension adds weight/mass to the bond head. Because of the high speed precision motions carried out by a bond head, such additional weight/mass is undesirable, and such a configuration may not be able to carry out the desired number of wire bonds in a given time period because of the additional weight/mass. Further, because of the limited wire length between the bonding tool and the tensioning device, an adequate wire length is not provided for certain looping motions. Further still, the wire length between the air guide and the tensioner is not subject to the variable tension, which may result in a non-optimized tension setting for said wire length.

Thus, it would be desirable to a wire feed system for a wire bonding machine overcoming one or more of the deficiencies of the prior art.

### SUMMARY OF THE INVENTION

According to an exemplary embodiment of the present invention, a wire feed system for a wire bonding machine is provided. The wire feed system includes (1) a wire supply, and (2) an air guide for receiving a length of wire from the wire supply. The air guide has an air inlet for receiving a pressurized fluid. The wire feed system is configured to apply a variable tension to the length of wire received by the air guide.

According to another exemplary embodiment of the present invention, a method of operating a wire feed system of a wire bonding machine is provided. The method includes providing a length of wire to an air guide of the wire feed system. The method also includes varying a tension applied to at least a portion of the length of wire provided to the air guide.

### BRIEF DESCRIPTION OF THE DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a front view of a wire bonding machine in accordance with an exemplary embodiment of the present invention;

FIG. 2 is a front view of certain components of a wire bonding machine in accordance with an exemplary embodiment of the present invention;

FIGS. 3A-3C are block diagrams of a wire feed system in accordance with an exemplary embodiment of the present invention;

FIGS. 4A-4B are block diagrams of a wire feed system in accordance with another exemplary embodiment of the present invention;

FIGS. 5A-5B are block diagrams of a wire feed system in accordance with yet another exemplary embodiment of the present invention; and

FIG. 6 is a block diagram view of a portion of a wire feed system in accordance with an exemplary embodiment of the present invention.

### DETAILED DESCRIPTION OF THE INVENTION

U.S. Pat. No. 5,402,927 entitled “Adjustable Wire Tensioning Apparatus,” and United States Patent Application Publication No. US 2006/0065695 entitled “Wire Feed System For A Wire Bonding Apparatus,” relate to wire bonding technology, and in particular to wire feed and tensioning systems, and are herein incorporated by reference in their entirety.

In the art of wire bonding, sufficient tension is applied to a wire during the wire bonding cycle, for example, (1) to help ball seating and (2) to prevent wire damage during high speed motions. At different portions of the wire bonding cycle, a desired (e.g., ideal) tension is different than at other portions of the wire bonding cycle. For example, during high speed motions (e.g., ascending to a reset height along the Z-axis, descending to first bond, etc.) a relatively high tension is desirable, for example, to be able to pull excess wire back (e.g., during ascension to reset height) and to seat the ball (e.g., while descending to first bond). In contrast, during certain looping motions, a significantly lower tension is desired because excessive tension could pull out bends made during the looping motions.

In a conventional wire bonding system that does not include a variable tension wire feed system, a single wire tension may be selected at the wire feed system. This tension may, and likely will be, lower than is desired for certain non-looping motions, and as such, wire whipping and other wire instability issues may a rise. Further, this type of problem may be compounded because of the machine to machine tension variation (and perhaps the wire to wire tension variation) that will result.

According to the certain exemplary embodiments of the present invention, a wire feed system (e.g., including various control schemes and corresponding hardware designs) is provided that provides a variable tension to the wire depending upon the portion of the wire bonding cycle. More specifically, the tension level may be controlled by software in the control scheme based on which part of the wire cycle the bonder is going through.

An exemplary wire feed system provides the variable tension by controlling the wire location inside a device called an air guide. Such a wire feed system may include, for example, sensors (e.g., optical sensors), capstans, and a motor controlled wire spool turning mechanism that is configured to (1) feed wire and (2) pull back wire.

Exemplary steps of operating such a system are now summarized. First, before the start of the reset motion, the wire spool will turn to pull back wire until the wire has entered a high tension zone close to the air inlet. A feed sensor located near the air inlet will control the motor controlled wire spool, thereby controlling the wire position. The wire will be kept in the high tension zone until the z-position reaches 1^{st} bond. Second, at the start of the 1^{st} bond, wire spool will turn to feed wire so that the wire will approach a stop feed sensor of the air guide which is further away from the air inlet in comparison to the feed sensor. Thus, the wire enters the low tension zone where the wire will be kept during looping (e.g., until 2^{nd} bond is completed). Third, prior to the start of the z reset motion, the first step may be repeated (i.e., the wire spool will turn to pull back wire until the wire is entered into a high tension zone close to the air inlet). Using this exemplary method, the amount of the wire spool turning can be calculated so that the right amount of wire is fed out or pulled in to enter the desired tension zone. For example, this can be a parameter in the wire bonding machine. Many variations of this exemplary system/method are possible, for example, a capstan can be added to the top of the air guide so that during looping motion, the wire touches the capstan which further reduces the air tension.

Another exemplary wire feed system according to the present invention provides the variable wire tension by switching a valve between an “on” and an “off” position. For example, when the valve is on (i.e., open) a higher flow is provided, and thus, a higher tension is generated. When the valve is off (i.e., closed) a lower flow is provided, and thus, a lower tension is generated.

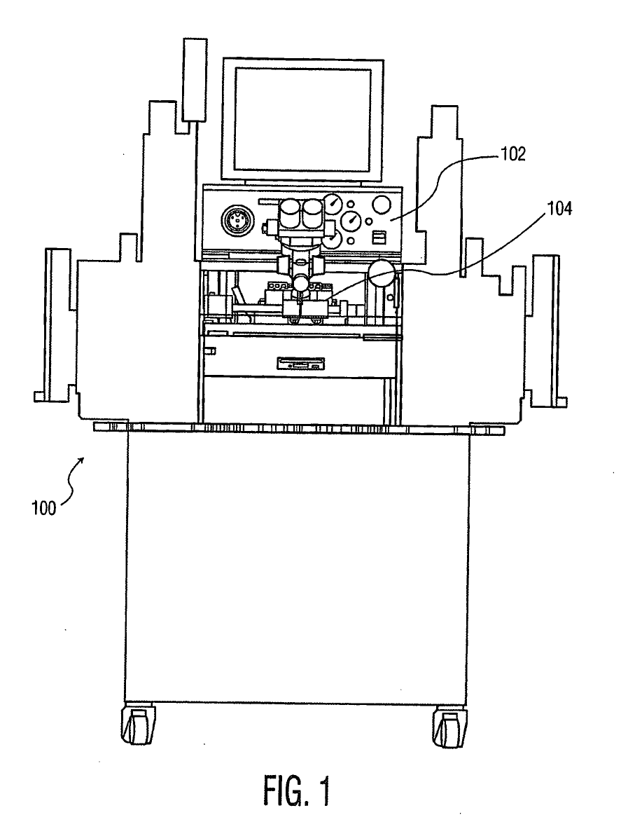

FIG. 1 illustrates wire bonding machine 100. Wire bonding machine 100 includes wire feed system 102 (sometimes referred to as the “upper console”) and optics housing/bondhead 104 (both wire feed system 102 and optics housing/bondhead 104 are partially covered by a microscope in FIG. 1). A conventional wire tensioner (not clearly illustrated in FIG. 1) may be mounted to optics housing/bondhead 104. Certain other components of wire bonding machine 100 are not shown in FIG. 1 for simplicity.

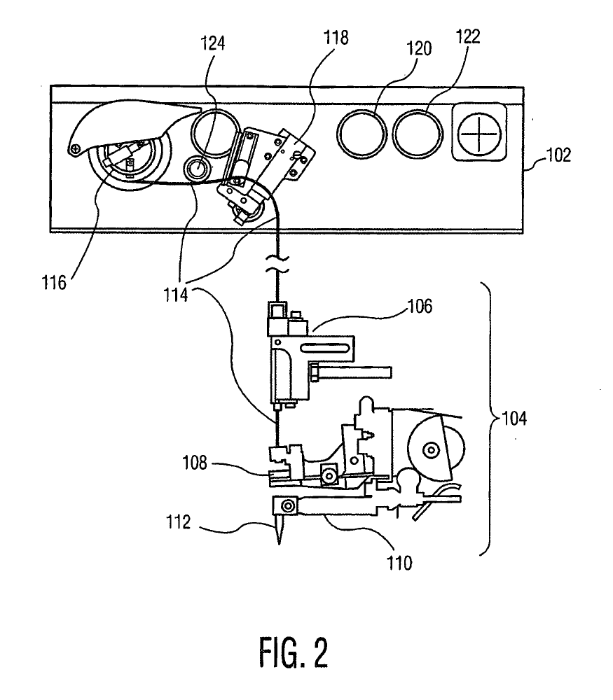

FIG. 2 is a more detailed view of certain components of wire bonding machine 100 including (1) wire feed system 102 and (2) components of optics housing/bondhead 104. The illustrated components of optics housing/bondhead 104 include wire tensioner 106, wire clamp assembly 108, ultrasonic transducer 110, and wire bonding tool 112 (other components of optics housing/bondhead 104, including certain components providing interconnection between the illustrated components of optics housing/bondhead 104, are not shown in FIG. 2).

Wire feed system 102 (of which certain components are omitted for clarity) includes wire spool mount 116 (configured to receive a wire supply such as a wire spool), wire guide bar 124 (e.g., diverter bar 124), air guide 118, air guide gauge 120, and tensioner gauge 122. These components are stationary elements of wire bonding machine 100 and do not travel with optics housing/bondhead 104. As illustrated in FIG. 2, wire 114 extends from wire spool mount 116 (where a spool that supplies length of wire 114 is not shown) and rides along wire guide bar 124 and components of air guide 118, ultimately being routed to wire bonding tool 112.

As provided above, in certain exemplary embodiments, the present invention relates to a wire feed system with variable tension. For example, the wire feed system may define multiple tension zones (e.g., high and low tension zones). Further, a fluid pressure (e.g., pressurized air) may be applied to the wire path of the wire feed system. By providing variable wire tension at the wire feed system of a wire bonding machine according to the present invention, a number of advantages are achieved. For example, the wire tension may be adjusted at the wire feed system based on the timing of the wire bonding cycle. Further, because the variable wire tension system is provided at the wire feed system, in contrast to being provided at the wire tensioning device, additional weight/mass may not be applied to the bond head carrying the wire tensioning device.

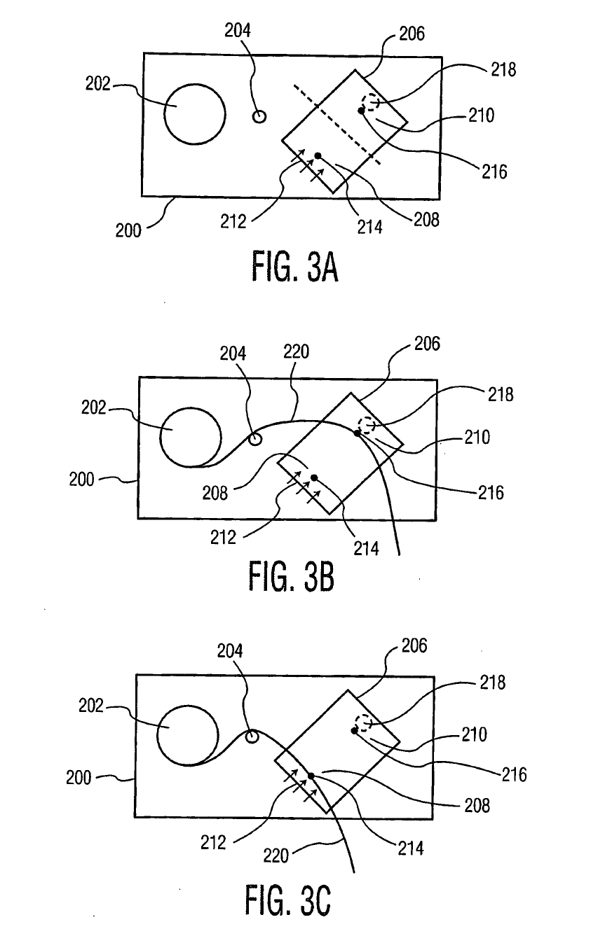

FIGS. 3A-3C, 4A-4B, 5A-5B, and 6 are block diagram illustrations of components of wire feed systems illustrating various exemplary features of the present invention. For example, such components may be used in conjunction with wire feed system 102 illustrated in FIG. 2, and/or in conjunction with wire bonding machine 100 illustrated in FIG. 1.

FIGS. 3A-3C are block diagrams of exemplary components of wire feed system 200 (e.g., wire feed system 200 may replace wire feed system 102 in FIG. 2). Referring specifically to FIG. 3A, wire feed system 200 is illustrated. Wire feed system 200 includes wire spool 202, wire guide bar 204 (e.g., diverter bar 204), and air guide 206. Air guide 206 defines high tension zone 208 and low tension zone 210. Air inlet 212 is also illustrated. A pressurized fluid (e.g., air) is injected into air guide 206 at air inlet 212. Because high tension zone 208 is in relatively close proximity to air inlet 212 (i.e., relatively close in comparison to low tension zone 210), high tension zone 208 receives more tension from the pressurized fluid entering air guide at air inlet 212. Conversely, because low tension zone 210 is relatively distant from air inlet 212 (i.e., relatively distant in comparison to high tension zone 208), low tension zone 210 receives less tension from the pressurized fluid entering air guide at air inlet 212.

Also shown in FIG. 3A is feed sensor 214, stop feed sensor 216, and capstan 218. For example, such exemplary elements may be provided (as described below) as detection elements (for use in the control scheme) or as stop/guide elements for defining a boundary of a tension zone. In the exemplary configuration illustrated in FIG. 3A, feed sensor 214 (and optionally a lower surface of air guide 206 adjacent stop feed sensor 214 but not shown in FIG. 3A) defines a point at which a wire passing through air guide 206 may be termed as being in high tension zone 208. Likewise, stop feed sensor 216 (and optionally capstan 218 adjacent stop feed sensor 216) defines a point at which a wire passing through air guide 206 may be termed as being in low tension zone 210.

While the sensors are illustrated in a given position, a wire may not necessarily need to be in contact with the sensor to define the position/zone of the sensor for use in the control scheme: the sensor may detect the position of the sensor without contact, where the detected position is used in the control scheme (e.g., to cause rotation of the wire spool mount motor).

In various exemplary embodiments of the present invention “capstans” are provided. As used herein the term “capstan” refers to a rotatable or a non-rotatable (e.g., fixed) member. In any event, whether rotatable or not, the capstans are intended to define a boundary for a wire.

As will be explained below with reference to FIGS. 3B-3C, rotation of wire spool 202 (e.g., using a spool mount motor or the like, not shown) can be utilized to move a wire fed through air guide 206 between high tension zone 208 and low tension zone 210. Thus, depending upon the portion of the wire bonding cycle, the tension applied to the wire through air guide 206 can be optimized.

Referring now to FIG. 3B, wire feed system 200 is shown with wire 220 extending through wire feed system 200. More specifically, wire 220 extends from wire spool 202, over diverter bar 204, through air guide 206 (in low tension zone 210), and downward towards the bond head assembly (not shown). If it is desired to move wire 220 from low tension zone 210 as shown in FIG. 3B to a position in high tension zone 208 as shown in FIG. 3C, wire spool 202 may be rotated, for example, clockwise, thus wrapping a portion of length of wire 220 around wire spool 202 and bringing length of wire 220 into high tension zone 208. When length of wire 220 comes in contact with (or in a predetermined proximity of) feed sensor 214, the control system (not shown) stops the clockwise rotation of wire spool 202 because length of wire 220 has entered high tension zone 208. As opposed to this clockwise rotation, another alternative would be to not feed additional wire during looping to second bond motions, which would pull the wire towards stop feed sensor 214.

Conversely, if it is desired to move wire 220 from high tension zone 208 as shown in FIG. 3C to a position in low tension zone 210 as shown in FIG. 3B, wire spool 202 may be rotated, for example, counterclockwise, thus feeding additional wire to length of wire 220 such that length of wire 220 is in low tension zone 210. When length of wire 220 comes in contact with (or in a predetermined proximity of) stop feed sensor 216, the control system (not shown) stops the counterclockwise rotation of wire spool 202 because length of wire 220 has entered low tension zone 210.

The positions of the sensors, and the position of the wire detected by the sensors as being in the high or low tension zone, may be optimized as is desired in a given configuration. Further, the sensors may even be located outside of the air guide while still providing the desired function. In a wire feed system having an air guide with a high tension zone and a low tension zone (such as the system illustrated in FIGS. 3A-3C), the control scheme (and the associated software) may be configured to position wire 220 in low tension zone 210 during looping motions (e.g., from 1^{st} bond to the top of the loop), and to position wire 220 in high tension zone 208 for certain non-looping motions (e.g., high speed z-motions, motions to reset electronic flame-off height, motions from the top of the loop to the 1^{st} bond tip, etc.).

While wire feed system 200 is described in terms of (1) a clockwise rotation of wire spool 202 to move from low tension zone 210 to high tension zone 208, and (2) a counterclockwise rotation of wire spool 202 to move from high tension zone 208 to low tension zone 210, this design in exemplary in nature. Depending upon the design of the wire feed system the rotations may be used to provide the opposite result.

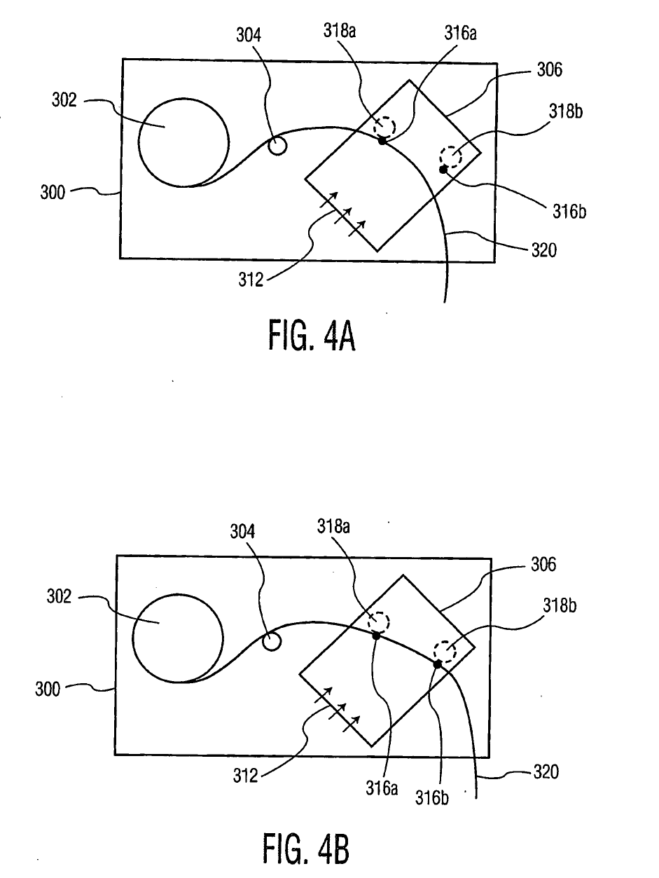

FIGS. 4A-4B are block diagrams of wire feed system 300 in accordance with an exemplary embodiment of the present invention. Wire feed system 300 includes wire spool 302, wire guide bar 304 (e.g., diverter bar 304), and air guide 306. Air inlet 312 is also illustrated. A pressurized fluid (e.g., pressurized air) is injected into air guide 306 at air inlet 312.

Also illustrated in FIGS. 4A-4B are sensor 316a, sensor 316b, capstan 318a, and capstan 318b. For example, such exemplary elements may be provided as detection elements (for use in the control scheme) or as stop/guide elements for defining a boundary of a tension zone. As illustrated in FIG. 4A, when wire 320 is in contact with (or in a predetermined proximity of) sensor 316a (and/or capstan 318a) but not in contact with (or in a predetermined proximity of) either sensor 316b or capstan 318b, wire 320 is in a high tension zone. As illustrated in FIG. 4B, when wire 320 is in contact with (or in a predetermined proximity of) sensor 316a (and/or capstan 318a), and is also in contact with (or in a predetermined proximity of) sensor 316b (and/or capstan 318b), wire 320 is in a low tension zone.

As is described above with respect to the exemplary embodiment of the present invention illustrated in FIGS. 3A-3C, in order to move from a high tension zone to a low tension zone (or vice versa) in wire feed system 300 illustrated in FIGS. 4A-4B, wire spool 302 may be rotated. For example, in order to switch from a high tension zone (as shown in FIG. 4A) to a low tension zone (as shown in FIG. 4B) wire spool 302 may be rotated counterclockwise to feed additional length to wire length 320 (e.g., until wire length 320 contacts or comes in a predetermined proximity of sensor 316b and/or capstan 318b). Conversely, in order to switch from a low tension zone (as shown in FIG. 4B) to a high tension zone (as shown in FIG. 4A) wire spool 302 may be rotated clockwise to draw a certain (predetermined) length from wire length 320 (e.g., until wire length 320 no longer contacts, or is no longer in a predetermined proximity of, sensor 316b and/or capstan 318b).

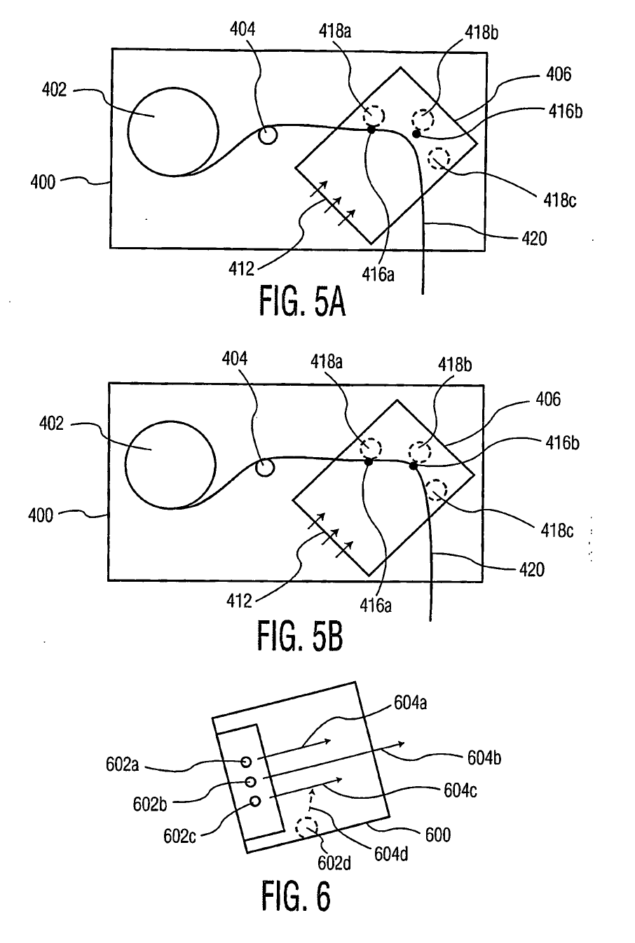

FIGS. 5A-5B are block diagrams of wire feed system 400 in accordance with an exemplary embodiment of the present invention. Wire feed system 400 (which is similar in certain respects to wire feed system 300 illustrated in FIGS. 44A-4B) includes wire spool 402, wire guide bar 404 (e.g., diverter bar 404), and air guide 406. Air inlet 412 is also illustrated. A pressurized fluid (e.g., pressurized air) is injected into air guide 406 at air inlet 412.

Also illustrated in FIGS. 5A-5B are sensor 416a, sensor 416b, capstan 418a, capstan 418b, and capstan 418c. For example, such exemplary elements may be provided as detection elements (for use in the control scheme) or as stop/guide elements for defining a boundary of a tension zone. As illustrated in FIG. 5A, when wire 420 is in contact with (or in a predetermined proximity of) sensor 416a (and/or capstan 418a) but not in contact with (or in a predetermined proximity of) either sensor 416b or capstan 418b, wire 420 is in a high tension zone. As illustrated in FIG. 5B, when wire 420 is in contact with (or in a predetermined proximity of) sensor 416a (and/or capstan 418a), and is also in contact with (or in a predetermined proximity of) sensor 416b (and/or capstan 418b), wire 420 is in a low tension zone. Wire feed system 400 differs from wire feed system 300 in that wire feed system 400 also includes optional capstan 418c which is in contact with wire 420 ad may be used to vary the wire tension as desired. For example, capstans such as capstan 418c may be provided to provide an opposing force/tension to the tension provided by the pressurized fluid, in order to ultimately provide the desired tension on wire 420.

As is described above with respect to the exemplary embodiments of the present invention illustrated in FIGS. 3A-3C and 4A-4B, in order to move from a high tension zone to a low tension zone (or vice versa) in wire feed system 400 illustrated in FIGS. 5A-5B, wire spool 402 may be rotated. For example, in order to switch from a high tension zone (as shown in FIG. 5A) to a low tension zone (as shown in FIG. 5B) wire spool 402 may be rotated counterclockwise to feed additional length to wire length 420 (e.g., until wire length 420 contacts or comes in the predetermined proximity of sensor 416b and/or capstan 418b). Conversely, in order to switch from a low tension zone (as shown in FIG. 5B) to a high tension zone (as shown in FIG. 5A) wire spool 402 may be rotated clockwise to draw a certain (predetermined) length from wire length 420 (e.g., until wire length 420 no longer contacts, or is no longer in a predetermined proximity of, sensor 416b and/or capstan 418b).

According to certain exemplary embodiments of the present invention, the location of the capstans (e.g., capstans 318a and 318b in FIGS. 4A-4B; capstans 418A, 418B, and 418C in FIGS. 5A-5B) and/or the associated sensors may be asymmetric with one another to achieve the varying tension effect. For example, the right hand capstan(s) and/or sensor(s) (e.g., capstan 318b and/or sensor 316b in FIGS. 4A-4B) may be positioned farther from the wire than the left hand capstan(s) and/or sensor(s) (e.g., capstan 318a and/or sensor 316a in FIGS. 4A-4B).

In the exemplary embodiments of the present invention illustrated in FIGS. 3A-3C, 4A-4B, and 5A-5B, adjustment of the respective wire feed system from a high tension zone to a low tension zone is accomplished through rotation of the wire spool in conjunction with sensors and/or capstans; however, the present invention contemplates any of a number of mechanisms or methods for adjusting the tension in the wire feed system.

FIG. 6 illustrates one exemplary alternative mechanism contemplated for adjusting the tension in the wire feed system. FIG. 6 is a simplified block diagram of air guide 600, where air guide 600 may be used in a wire feed system such as those illustrated in FIGS. 3A-3C, 4A-4B, and 5A-5B. In contrast to air guides 206, 306, and 406 described above, air guide 600 includes selectively operable air inlets 602a, 602b, and 602c. In order to adjust the tension in a wire feed system including air guide 600, the desired operational configuration of air inlets 602a, 602b, and 602c is selected. For example, air inlets 602a and 602c may be configured to provide air pressure (through air streams 604a and 604c) to provide a low tension in air guide 600. During such low tension, air inlet 602b may be selected to be in an “off” or “closed valve” position. In order to switch to a high tension in air guide 600, air inlet 602b may be selected to be in an “on” or “open valve” position. Thus, when air pressure is provided though each of air inlets 602a, 602b, and 602c (through air streams 604a, 604b, and 604c), air guide 600 is in a high tension.

When in the “on” or “open valve” position, air inlets 602a, 602b, and 602c may be configured to have the same or different air pressures associated therewith. For example, in the exemplary embodiment of the present invention shown in FIG. 6, air stream 604b is illustrated as longer than (and therefore having a higher air pressure than) air streams 604a and 604b. Other arrangements (e.g., all inlets having the same air pressure, inlet 604b having a lower pressure than inlets 604a/604c, etc.) are also contemplated as within the scope of the present invention.

Of course, alternate valve schemes are contemplated. For example, not all inlets need to receive the pressurized fluid in order for the system to be in a high tension mode. More specifically, certain inlet(s) may receive pressurized fluid in low tension mode, while other inlet(s) may receive pressurized fluid in high tension mode. Thus, the valves associated with the inlets may be “switched.”

Further, it is understood that FIG. 6 provides only one example of a “valved” system. It is contemplated that the air inlets for the air guide may be provided in any of a number of different positions depending upon the desired design. For example, one or more inlets may be provided at the illustrated inlet side of the air guide, while one or more other inlets may be provided at a different area (a side portion) of the air guide (See, for example, optional inlet 602d and air stream 604d shown in dotted lines in FIG. 6). Thus, the pressurized fluid may be directed as is desired based on the design.

Further still, a single inlet (or group of inlets) may be provided to be used for both high and low tension, but the fluid pressure passing through those inlets may be varied based upon the portion of the wire bonding cycle.

Thus, according to the various exemplary variable tension systems and methods described herein, a number of advantages are achieved. A different (e.g., desired) tension level can be provided for each part of the wire bonding cycle, thereby providing improved bonding results. For example, the speed used during certain non-looping motions (e.g., z reset, descent to 1^{st} speed, etc.) may be increased because of the increased wire tension during these motions. Often, these non-looping motions are performed at a reduced speed to provide better looping and ball seating. Additionally, the potential for wire damage and/or wire leaning may also be reduced because if a low tension is used during high speed motions wire whipping and/or wire buckle (amongst other potential issues) may result between the wire clamp and the tensioner.

Further still, the present invention may provide a reduced machine to machine looping variation. This is because when high tension is used on a wire bonding machine, the looping profile tends to be sensitive to variation of the tension which could be caused by machine to machine differences or wire location in the air guide. Through the present invention, by keeping the tension relatively low during looping motions, the looping will be more consistent.

While the present invention has been described primarily with respect to air, any of a number of pressurized fluids may be used as is desired.

While the present invention has been illustrated with respect to certain exemplary configurations (having a certain number and position of sensors and/or capstans), alternative configurations (having more or less, or differently positioned, sensors and/or capstans) are contemplated.

Any of a number of sensors may be used within the scope of the present invention, including but not limited to: proximity sensors, contact sensors, motion sensors, etc.

While certain exemplary embodiments of the present invention have been described with respect to a high tension zone and a low tension zone, the present invention is not limited thereto. For example, there may be more than two tension zones within a wire feed system of the present invention.

While the present invention has been described primarily in connection with wire feed systems and methods of operating wire feed systems, it is not limited thereto. For example, the present invention may be embodied in a wire bonding machine including a wire feed system as described herein, amongst other components such as a control system for operating the wire feed system. Alternatively, the present invention may be embodied as a method of operating a wire bonding machine.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A wire feed system for a wire bonding machine, the wire feed system comprising:
a wire supply; and
an air guide for receiving a length of wire from the wire supply, the air guide having an air inlet for receiving a pressurized fluid,
the wire feed system being configured to apply a variable tension to the length of wire received by the air guide.

2. The wire feed system of claim 1 wherein the air guide defines a plurality of tension zones, each of the zones applying a different tension to the length of wire received by the air guide.

3. The wire feed system of claim 2 wherein the plurality of tension zones includes a high tension zone and a low tension zone.

4. The wire feed system of claim 2 further comprising a plurality of stop elements for defining a boundary of each of the plurality of tension zones.

5. The wire feed system of claim 4 wherein the stop elements includes at least one of a sensor, a capstan, and an air guide surface.

6. The wire feed system of claim 1 wherein the wire supply includes a wire spool.

7. The wire feed system of claim 6 wherein the wire spool is configured to rotate in order to move the length of wire from one of the tension zones to another of the tension zones.

8. The wire feed system of claim 7 wherein the wire spool is configured (1) to rotate clockwise to move the length of wire from one of a high tension zone and a low tension zone to the other of the high tension zone and the low tension zone, and (2) to rotate counterclockwise to move the length of wire from one of the high tension zone and the low tension zone to the other of the high tension zone and the low tension zone.

9. The wire feed system of claim 1 further comprising a diverter bar positioned between the wire supply and the air guide.

10. The wire feed system of claim 1 wherein the air inlet includes a plurality of air inlets for receiving the pressurized fluid.

11. The wire feed system of claim 10 wherein at least one of the air inlets is selectively operable such that a magnitude of the pressurized fluid received by the air guide varies based on which of the air inlets is selected to receive the pressurized fluid.

12. A method of operating a wire feed system of a wire bonding machine, the method comprising the steps of:
providing a length of wire to an air guide of the wire feed system; and
varying a tension applied to at least a portion of the length of wire provided to the air guide.

13. The method of claim 12 wherein the varying step includes moving at least the portion of the length of wire from one of a plurality of tension zones of the air guide to another of the plurality of tension zones of the air guide.

14. The method of claim 13 wherein the moving step includes moving at least the portion of the length of wire from one of a high tension zone and a low tension zone to the other of the high tension zone and the low tension zone.

15. The method of claim 13 wherein the moving step includes moving at least the portion of the length of wire to be in contact with, or within a predetermined proximity of, at least one of a plurality of stop elements defining a boundary of at least one of the plurality of tension zones.

16. The method of claim 15 wherein the moving step includes moving at least the portion of the length of wire to be in contact with, or within a predetermined proximity of, at least one of a sensor, a capstan, and an air guide surface defining a boundary of at least one of the plurality of tension zones.

17. The method of claim 12 wherein the providing step includes providing the length of wire from a wire spool positioned in the wire feed system.

18. The method of claim 17 wherein the varying step includes rotating the wire spool to move at least the portion of the length of wire from one of a plurality of tension zones of the air guide to another of the tension zones of the air guide.

19. The method of claim 18 wherein the rotating step includes at least one of (1) rotating the wire spool clockwise to move the portion of the length of wire from one of a high tension zone and a low tension zone to the other of the high tension zone and the low tension zone, and (2) rotating the wire spool counterclockwise to move the portion of the length of wire from one of the high tension zone and the low tension zone to the other of the high tension zone and the low tension zone.

20. The method of claim 12 wherein the varying step includes varying a fluid pressure provided to at least one air inlet defined by the air guide.

21. The method of claim 20 wherein the step of varying the fluid pressure includes selectively providing or removing fluid pressure provided to at least one of a plurality of air inlets defined by the air guide to vary the tension applied to the length of wire.
